(19) United States
(12) Patent Application Publication
(10) Pub. No.: US 2026/0040431 A1
(43) Pub. Date: Feb. 5, 2026

(54) MULTILAYER WIRING BOARD AND ELECTRONIC DEVICE INCLUDING THE SAME

(71) Applicant: Fujitsu Limited, Kawasaki-shi (JP)

(72) Inventor: Ryo Kikuchi, Sagamihara (JP)

(73) Assignee: Fujitsu Limited, Kawasaki-shi (JP)

(21) Appl. No.: 19/280,260

(22) Filed: Jul. 25, 2025

(30) Foreign Application Priority Data
Jul. 31, 2024 (JP) 2024-124865

(51) Int. Cl. H05K 1/02; H05K 1/11; H05K 1/18

(52) U.S. Cl. CPC H05K 1/0213; H05K 1/115; H05K 1/181

(57) ABSTRACT

A multilayer wiring board has a first signal layer and ground layers, and includes a first differential wiring provided in the first signal layer and including first and second wirings, a first another signal line provided on the first signal layer, a signal via extending along the stacking direction and electrically connected to the first another signal line, and a ground via extending along a stacking direction and electrically connected to the ground layers. The first differential wiring includes a first portion, a second portion continuous with the first portion, and a third portion continuous with the second portion, the first wiring being disposed between the ground via and the signal via adjacent to the ground via, the second wiring being disposed on an opposite side of the first wiring across the ground via, and the ground via being sandwiched between the first and second wirings.

### CROSS-REFERENCE TO RELATED APPLICATION

This application is based upon and claims the benefit of priority of the prior Japanese Patent Application No. 2024-124865, filed on Jul. 31, 2024, the entire contents of which are incorporated herein by reference.

### FIELD

A certain aspect of embodiments described herein relates to a multilayer wiring board and an electronic device including the multilayer wiring board.

### BACKGROUND

There is known a board on which a pair of differential wirings, each consisting of two wires, and a differential signal via pair to which the differential wirings are electrically connected are formed (see, for example, Japanese Patent Application Publication No. 2017-212411 hereinafter referred to as Patent Document 1). Such a board is a multilayer wiring board with multiple signal layers, and may have multiple differential wirings formed thereon. As the number of differential wirings increases, the number of differential signal via pairs also increases.

### SUMMARY

According to an aspect of the present invention, there is provided a multilayer wiring board having at least a first signal layer and a plurality of ground layers along a stacking direction, the multilayer wiring board including: a first differential wiring that is provided in the first signal layer and includes a first wiring and a second wiring; a first another signal line provided on the first signal layer; a signal via that extends along the stacking direction and is electrically connected to the first another signal line; and a ground via that extends along the stacking direction and is electrically connected to the plurality of ground layers, wherein the first differential wiring includes a first portion, a second portion continuous with the first portion, and a third portion continuous with the second portion, the first wiring being disposed between the ground via and the signal via adjacent to the ground via, the second wiring being disposed on an opposite side of the first wiring across the ground via, and the ground via being sandwiched between the first wiring and the second wiring.

According to an aspect of the present invention, there is provided an electronic device including: a multilayer wiring board having at least a first signal layer and a plurality of ground layers along a stacking direction, the multilayer wiring board comprising: a first differential wiring that is provided in the first signal layer and includes a first wiring and a second wiring; a first another signal line provided on the first signal layer; a signal via that extends along the stacking direction and is electrically connected to the first another signal line; and a ground via that extends along the stacking direction and is electrically connected to the plurality of ground layers, wherein the first differential wiring includes a first portion, a second portion continuous with the first portion, and a third portion continuous with the second portion, the first wiring being disposed between the ground via and the signal via adjacent to the ground via, the second wiring being disposed on an opposite side of the first wiring across the ground via, and the ground via being sandwiched between the first wiring and the second wiring; and an electronic component mounted on the multilayer wiring board.

The object and advantages of the invention will be realized and attained by means of the elements and combinations particularly pointed out in the claims. It is to be understood that both the foregoing general description and the following detailed description are exemplary and explanatory and are not restrictive of the invention, as claimed.

### BRIEF DESCRIPTION OF DRAWINGS

FIG. 1 is a plan view of an example of an electronic device in which an electronic component is mounted on a multilayer wiring board of an embodiment;

FIG. 2 is a plan view of a partial region of a multilayer wiring board of an embodiment;

FIG. 3 is a cross-sectional view of a multilayer wiring board of an embodiment taken along a line A1-A1 in FIG. 2;

FIG. 4 is a cross-sectional view of an enlarged portion of a cross-sectional view of a line A1-A1 in FIG. 3;

FIG. 5 is a cross-sectional view of a multilayer wiring board of an embodiment taken along a line A2-A2 in FIG. 2;

FIG. 6A is a plan view of a partial region of a first signal layer in which a first differential wiring and a second differential wiring are provided;

FIG. 6B is a plan view of a partial region of a second signal layer in which a third differential wiring is provided;

FIG. 6C is a plan view of a partial region of a ground layer;

FIG. 6D is a plan view of a partial region of a shielding ground layer;

FIG. 7 is an explanatory diagram illustrating how a first differential wiring surrounds a ground via in a multilayer wiring board of an embodiment;

FIG. 8 is an enlarged view of a periphery of a clearance portion provided in a multilayer wiring board of an embodiment;

FIG. 9 is a plan view of a partial area of a multilayer wiring board of a comparative example;

FIG. 10 is a cross-sectional view of a multilayer wiring board of a comparative example taken along a line A3-A3 in FIG. 9;

FIG. 11A is a graph of results of EYE analysis of a multilayer wiring board of an embodiment; and

FIG. 11B is a graph of results of EYE analysis of a multilayer wiring board of a comparative example.

### DESCRIPTION OF EMBODIMENTS

In recent years, AI (Artificial Intelligence) technology has progressed remarkably, and electronic devices that can be applied to AI learning devices are being developed vigorously. Electronic devices capable of high-speed calculations are also being developed. These electronic devices incorporate electronic devices in which electronic components are mounted on a multilayer wiring board. As the development of these electronic devices progresses, the demand for high-density wiring in multilayer wiring boards is also increasing. A multilayer wiring board has multiple components. The multiple components are multiple differential wirings and multiple differential signal via pairs. As the wiring density in a multilayer wiring board increases, it is expected that electromagnetic waves will affect each other in various combinations of components. As electromagnetic waves affect each other between adjacent components, the signal of one component may become noise in the signal of the other component, and the signal of the other component may become noise in the signal of the one component. In other words, as the wiring density in a multilayer wiring board increases, it is expected that crosstalk caused by the influence of electromagnetic waves between components will increase. Patent Document 1 had room for improvement in terms of suppressing and reducing such crosstalk.

Below, an embodiment of the present invention will be described with reference to the attached drawings. However, the dimensions and ratios of each part in the drawings may not be illustrated to be completely consistent with the actual ones. The scales of the drawings may differ from one another. In addition, in some drawings, for convenience of explanation, components that actually exist may be omitted or dimensions may be exaggerated compared to the actual ones.

### Embodiment

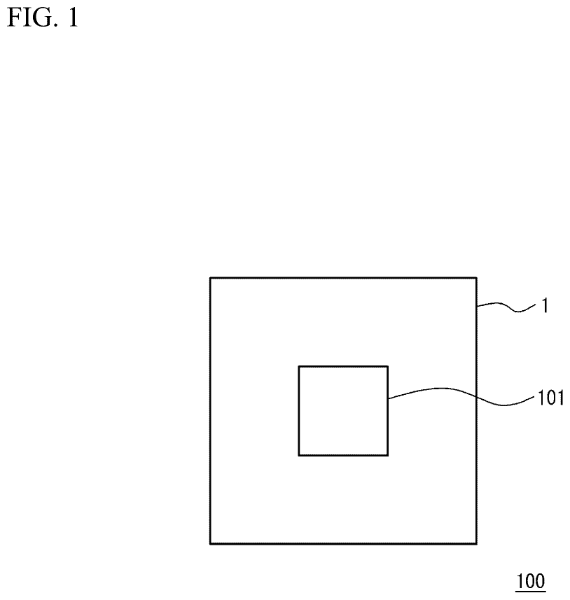

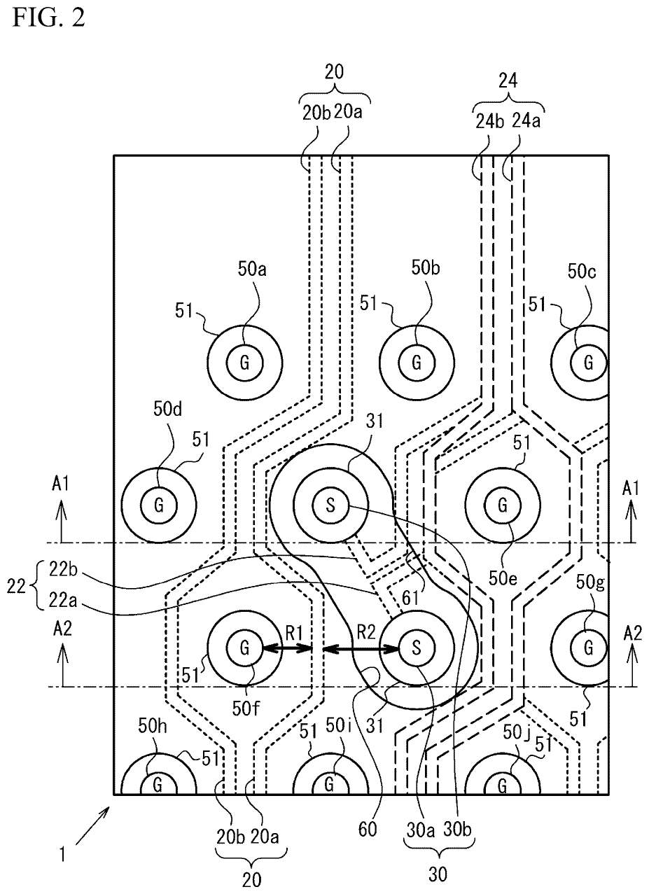

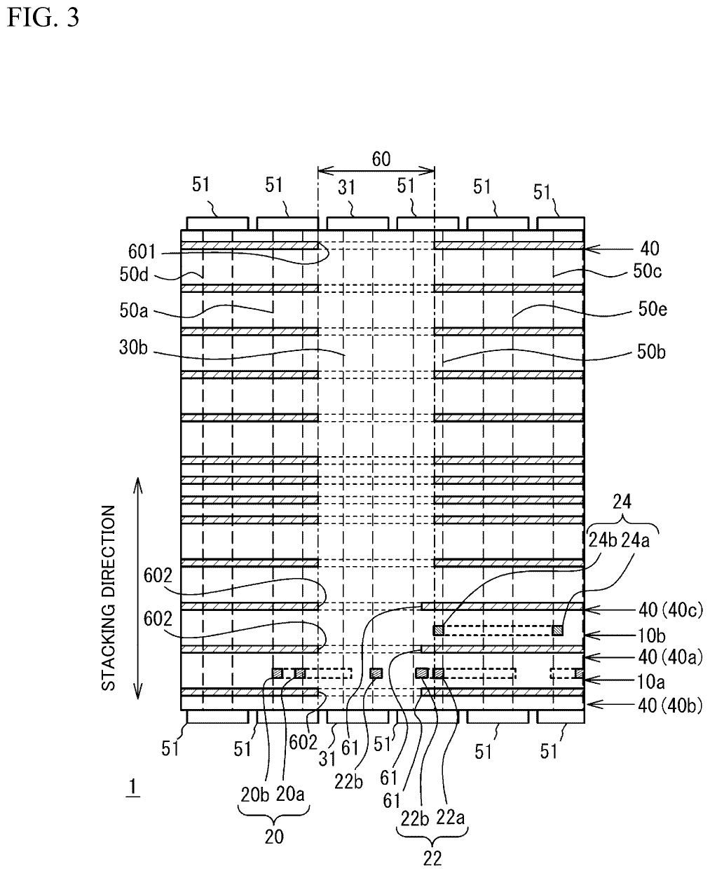

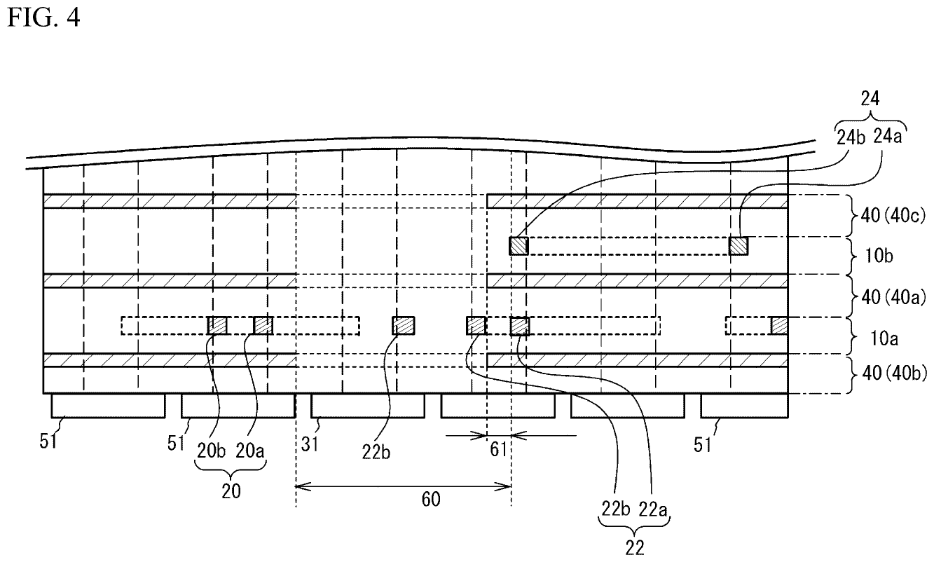

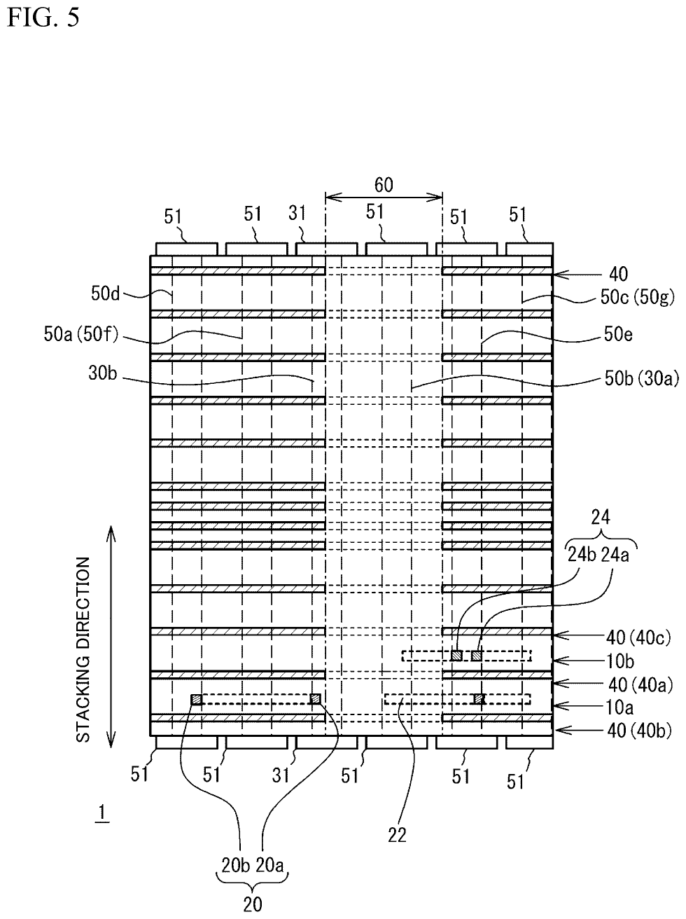

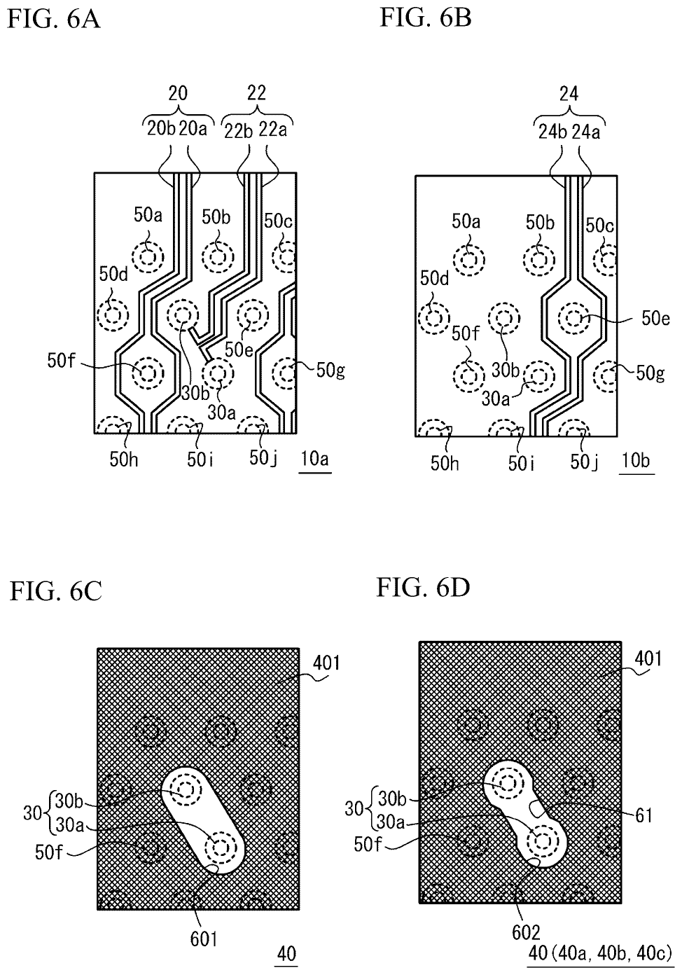

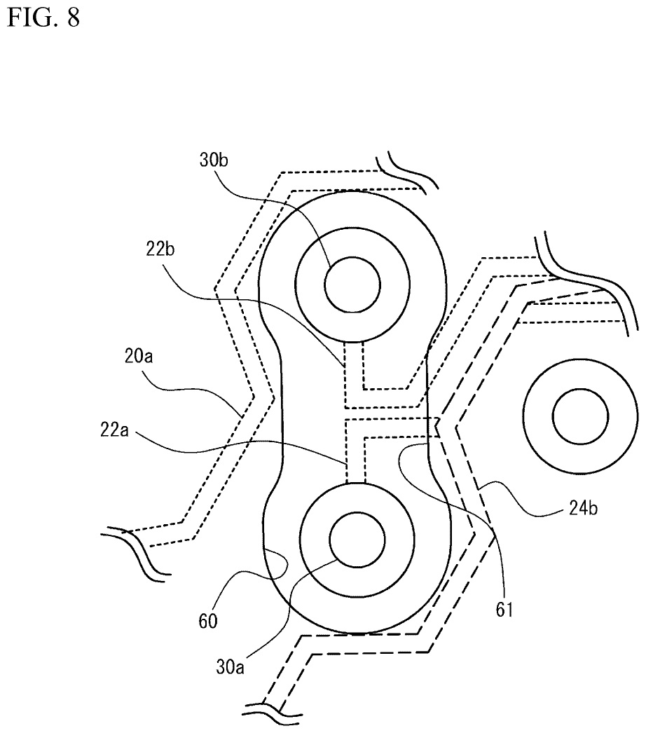

An electronic device 100 according to an embodiment will be described with reference to FIG. 1 to FIG. 8. Referring to FIG. 1, the electronic device 100 is formed by mounting an electronic component 101 on a multilayer wiring board (hereinafter simply referred to as “board”) 1. FIG. 2 is a plan view of a part of the board 1. FIG. 3 is a cross-sectional view of the board 1 taken along a line A1-A1 in FIG. 2, and FIG. 4 is a cross-sectional view of an enlarged portion of the board 1. FIG. 5 is a cross-sectional view of the board 1 taken along a line A2-A2 in FIG. 2. FIG. 6A is a plan view of a partial area of a first signal layer 10a (see FIG. 3 and FIG. 4) in which a first differential wiring 20 and a second differential wiring 22 are provided. FIG. 6B is a plan view of a partial area of a second signal layer 10b (see FIG. 3 and FIG. 4) in which a third differential wiring 24 is provided. FIG. 6C is a plan view of a partial area of a ground layer 40 (see FIG. 3 and FIG. 4). FIG. 6D is a plan view of a partial area of shielding ground layers 40a, 40b, and 40c (see FIG. 3 and FIG. 4). In order to easily distinguish the first differential wiring 20, the second differential wiring 22, and the third differential wiring 24, these differential wirings are illustrated with different line types in FIG. 2 and FIG. 8. Specifically, the first differential wiring 20 and the second differential wiring 22 provided in the first signal layer 10a are illustrated by dotted lines, and the third differential wiring 24 provided in the second signal layer 10b is illustrated by dashed lines.

The board includes the first signal layer 10a, the second signal layer 10b, and the ground layer 40, which are stacked along the stacking direction illustrated in FIG. 3. The board 1 also includes a first signal via 30a and a second signal via 30b extending along the stacking direction. The board 1 also includes a plurality of ground vias 50a and the like extending along the stacking direction.

As illustrated in FIG. 6A, the first signal layer 10a includes the first differential wiring 20 and the second differential wiring 22. The second differential wiring 22 corresponds to a first another signal line provided in the first signal layer 10a. The first differential wiring 20 includes a first wiring 20a and a second wiring 20b. In other words, the first differential wiring 20 is formed by pairing the first wiring 20a and the second wiring 20b. The second differential wiring 22 includes a third wiring 22a and a fourth wiring 22b. That is, the second differential wiring 22 is formed by pairing the third wiring 22a and the fourth wiring 22b. The first differential wiring 20 and the second differential wiring 22 can be formed by a conventional method such as performing an etching process on a resin layer as an insulating material forming the first signal layer 10a. The first signal layer 10a may have another signal lines other than the first differential wiring 20 and the second differential wiring 22. FIG. 6A also illustrates differential wiring other than the first differential wiring 20 and the second differential wiring 22. In the cross-sectional views illustrated in FIG. 3 to FIG. 5, hatching of the resin layer parts forming each layer of the first signal layer 10a, the second signal layer 10b, and the ground layer 40 is omitted.

The first signal via 30a and the second signal via 30b are paired to form a differential signal via pair 30. In the state illustrated in FIG. 2, the first signal via 30a and the second signal via 30b have a right-shouldered downward positional relationship. In other words, when the second signal via 30b is used as a reference, the first signal via 30a is located to the lower right of the second signal via 30b. The differential signal via pair 30 is electrically connected to the second differential wiring 22. Specifically, the third wiring 22a is electrically connected to the first signal via 30a. The fourth wiring 22b is electrically connected to the second signal via 30b. The board 1 has a differential signal via pair in an area other than the area illustrated in each figure, and the first differential wiring 20 is electrically connected to a differential signal via pair not illustrated. Both ends of the first signal via 30a and the second signal via 30b face the surface layer of the board 1, and each is provided with a conductor portion 31. The conductor portion 31 is used for soldering when mounting the electronic component 101.

As illustrated clearly in FIG. 6B, the second signal layer 10b is provided with the third differential wiring 24. The third differential wiring 24 corresponds to a second another signal line provided in the second signal layer 10b. The third differential wiring 24 includes a fifth wiring 24a and a sixth wiring 24b. That is, the third differential wiring 24 is formed by pairing the fifth wiring 24a and the sixth wiring 24b. The third differential wiring 24 is electrically connected to a differential signal via pair not illustrated. In this embodiment, the first signal layer 10a and the second signal layer 10b are provided, but a form having more signal layers may be used. In addition, the second signal layer 10b may be provided with signal lines other than the third differential wiring 24.

The umber of the ground layer 40 is two or more. Of the multiple ground layers 40, the layer provided between the first signal layer 10a and the second signal layer 10b is the first shielding ground layer 40a. The first shielding ground layer 40a is the layer directly above the first signal layer 10a and directly below the second signal layer 10b. Of the multiple ground layers 40, the layer provided below the first signal layer 10a is the second shielding ground layer 40b. The second shielding ground layer 40b is the layer directly below the first signal layer 10a. Of the multiple ground layers 40, the layer provided above the second signal layer 10b is the third shielding ground layer 40c. The third shielding ground layer 40c is the layer directly above the second signal layer 10b.

As a result, in this embodiment, shielding ground layers are provided above and below the first signal layer 10a, and shielding ground layers are provided above and below the second signal layer 10b.

The shielding ground layers 40a, 40b, and 40c can shield electromagnetic waves associated with signal transmission in the board 1 and reduce crosstalk between the second differential wiring 22 and the third differential wiring 24. As illustrated clearly in FIG. 6C and FIG. 6D, the ground layer 40 has wiring, that is, a ground solid pattern 401. The ground layers 40 other than the shielding ground layers 40a, 40b, and 40c have a first clearance region 601 formed between the ground solid pattern 401 and the differential signal via pair 30. The shielding ground layers 40a, 40b, and 40c have a second clearance region 602 formed between the ground solid pattern 401 and the differential signal via pair 30, and also have an eaves portion 61. The ground layer 40 having the first clearance region 601 and the shielding ground layers 40a, 40b, and 40c having the second clearance region 602 are stacked to form a clearance portion 60. The clearance portion 60, the second clearance region 602, and the eaves portion 61 will be described in detail later.

The board 1 has ground vias 50a to 50j in the area illustrated in FIG. 2. Both ends of the ground vias 50a to 50j face the surface layer of the board 1, and each is provided with a conductor portion 51. The ground vias 50a to 50j are electrically connected to the ground layer 40. The ground vias 50a to 50j are arranged in a grid pattern together with the first signal via 30a and the second signal via 30b when the board 1 is viewed from the stacking direction. In FIG. 2, the ground vias 50a, 50b, and 50c are arranged in the same row. The ground via 50d, the second signal via 30b, and the ground via 50e are arranged in the same row. The ground via 50f, the first signal via 30a, and the ground via 50g are arranged in the same row. The ground vias 50h, 50i, and 50j are arranged in the same row. The adjacent rows are shifted by ½ column in the left-right direction in FIG. 2. Note that the arrangement of the vias illustrated in FIG. 2 is an example and is not limited to this.

### [Wiring Path of Differential Wiring]

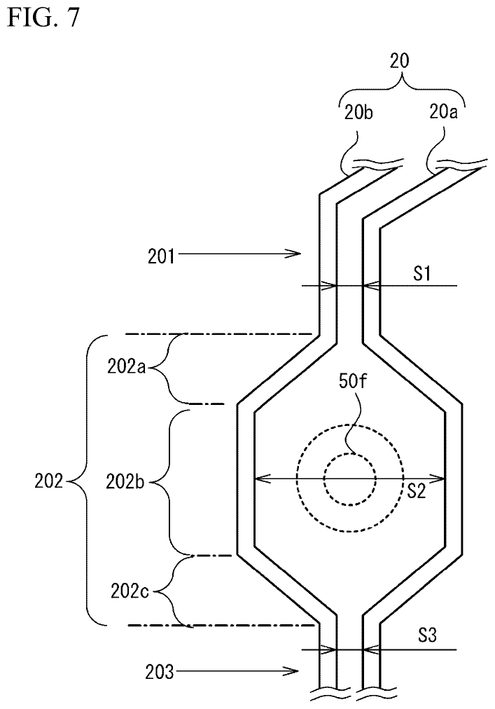

Next, the wiring path of the differential wiring in the first signal layer 10a will be described in detail. Here, the first differential wiring 20 will be described in particular. In FIG. 7, the first differential wiring 20 includes a first portion 201, a second portion 202a, a third portion 202b, a fourth portion 202c, and a fifth portion 203. Differential wiring can have various wiring paths, but in general differential wiring, even if the path is curved, the distance between two wirings in a pair is generally constant. In contrast, the first differential wiring 20 of the present embodiment has a portion where the distance between the two wirings is different, as described below

The first wiring 20a and the second wiring 20b in the first portion 201 are parallel, and the distance between them is a distance S1.

The second portion 202a is a portion continuous with the first portion 201. In the second portion 202a, the distance between the first wiring 20a and the second wiring 20b varies depending on the position along the wiring path of the first differential wiring 20. Specifically, the distance between the first wiring 20a and the second wiring 20b in the second portion 202a becomes larger than the distance S1 as it moves away from the first portion 201. In the second portion 202a, the distance between the first wiring 20a and the second wiring 20b is the largest at the end opposite to the end continuous with the first portion 201, and the distance is a distance S2.

The third portion 202b is a portion continuous with the second portion 202a. The third portion 202b is continuous with the second portion 202a on the opposite side to the first portion 201. In the third portion 202b, the first wiring 20a and the second wiring 20b are parallel, and the distance between them is a distance S2.

In the second portion 202a of this embodiment, the distance between the first wiring 20a and the second wiring 20b gradually increases from the first portion 201 toward the third portion 202b. However, the second portion 202a may have other configurations as long as it can connect the first portion 201 and the third portion 202b, in which the distance between the first wiring 20a and the second wiring 20b is different. For example, the angle of the connection portion between the first portion 201 and the second portion 202a may be approximately a right angle, and the angle of the connection portion between the second portion 202a and the third portion 202b may be approximately a right angle. Also, the second portion 202a may be curved to connect the first portion 201 and the third portion 202b.

Referring now to FIG. 2, the ground via 50f and the first signal via 30a are adjacent to each other in the left-right direction. In the third portion 202b, the first wiring 20a is disposed between the ground via 50f and the first signal via 30a. The second wiring 20b is disposed on the opposite side of the first wiring 20a, with the ground via 50f in between. As a result, in the third portion 202b, the ground via 50f is sandwiched between the first wiring 20a and the second wiring 20b.

The fourth portion 202c is a portion that is continuous with the third portion 202b. The fourth portion 202c is continuous with the third portion 202b on the opposite side to the second portion 202a. In the fourth portion 202c, the distance between the first wiring and the second wiring varies depending on the position along the wiring path of the first differential wiring. Specifically, the distance between the first wiring 20a and the second wiring 20b in the fourth portion 202c becomes smaller than the distance S2 as it moves away from the third portion 202b. In the fourth portion 202c, the distance between the first wiring 20a and the second wiring 20b is the smallest at the end opposite the end that is continuous with the third portion 202b, and the distance is a distance S3. In this embodiment, the distance S1 and the distance S3 are approximately equal. That is, the minimum distance between the first wiring 20a and the second wiring 20b in the fourth portion 202c is the same as the distance between the first wiring 20a and the second wiring 20b in the first portion 201. However, the distance S3 and the distance S1 may be different, and it is sufficient that the distance S2 is greater than the distance S3.

The fifth portion 203 is a portion that continues with the fourth portion 202c. The fifth portion 203 continues on the opposite side of the fourth portion 202c from the third portion 202b. The first wiring 20a and the second wiring 20b in the fifth portion 203 are parallel, and the distance between them is a distance S3. In this embodiment, the distance S3 is approximately equal to the distance S1. However, as described above, the distance S3 may be different from the distance S1. By providing the fifth portion 203, the first differential wiring 20 can pass between the ground vias.

In the fourth portion 202c of this embodiment, the distance between the first wiring 20a and the second wiring 20b gradually narrows from the third portion 202b toward the fifth portion 203. However, the fourth portion 202c may have other configurations as long as it can connect the third portion 202b and the fifth portion 203, in which the distance between the first wiring 20a and the second wiring 20b is different. For example, the angle of the connection portion between the third portion 202b and the fourth portion 202c may be approximately a right angle, and the angle of the connection portion between the fourth portion 202c and the fifth portion 203 may also be approximately a right angle. Furthermore, the fourth portion 202c may be a curved line connecting the third portion 202b and the fifth portion 203.

In this way, the board 1 of this embodiment forms an enclosure 202 that surrounds the ground via 50f using the second portion 202a, the third portion 202b, and the fourth portion 202c.

By forming the enclosure 202, it is possible to make it possible to pass only the first wiring 20a between the ground via 50f and the first signal via 30a. Since it is only necessary to provide a single wiring between the ground via 50f and the first signal via 30a, the degree of freedom in arranging the differential wiring is improved in the board 1 with high wiring density. As a result, in the board 1 with high wiring density, the distance between the differential signal via pair 30 to which the second differential wiring 22 is connected and the first differential wiring 20 can be increased, and crosstalk caused by electromagnetic interference can be suppressed and reduced.

Now, returning to FIG. 2, the interval R1 between the first wiring 20a and the ground via 50f, and the interval R2 between the first wiring 20a and the first signal via 30a will be described. Referring to FIG. 2, the interval R2 is wider than the interval R1. In other words, in the third portion 202b, the first wiring 20a can be moved closer to the ground via 50f and spaced apart from the first signal via 30a.

The first wiring 20a belongs to the first differential wiring 20. And the first signal via 30a is connected to the second differential wiring 22, which is different from the first differential wiring 20. For this reason, there is a possibility that both signals become noise for each other. To address this phenomenon, in the board 1 of this embodiment, the interval R2 is set wide and the first wiring 20a is spaced apart from the first signal via 30a, thereby avoiding electromagnetic interference. As a result, the two signals are prevented from becoming noise for each other, and crosstalk is suppressed.

The position where the enclosure 202 is formed can be appropriately set in consideration of the entire wiring path on the board 1. In the example illustrated in FIG. 2, the enclosure may be formed at a location where the ground via 50d and the second signal via 30b are adjacent to each other according to the wiring path. The enclosure may also be formed at a location where the ground via 50a and the second signal via 30b are adjacent to each other, or where the ground via 50i and the first signal via 30a are adjacent to each other. The enclosure can also be formed in a similar manner when a differential wiring other than the first differential wiring 20 is disposed near the differential signal via pair 30. In FIG. 6A, an enclosure surrounding the ground via 50g is illustrated. Furthermore, in this embodiment, only the wiring path within the area shown in FIG. 2 is described, but a wiring path similar to the enclosure 202 can be set in an area not illustrated in FIG. 2.

Furthermore, in this embodiment, the setting of the enclosure 202 in the first signal layer 10a is described, but the enclosure can be set in a similar manner in other signal layers. Referring to FIG. 6B, the third differential wiring 24 provided in the second signal layer 10b also has an enclosure surrounding the ground via 50e. The formation of an enclosure in the third differential wiring 24 is also effective in that it can separate the sixth wiring 24b from the differential signal via pair 30. If the differential wirings overlap in the clearance portion 60, which will be described later, this can cause crosstalk between the differential wirings. By forming an enclosure and placing one wiring between the ground via and the first signal via 30a or the second signal via 30b, it becomes easier to avoid overlapping of the differential wirings in the clearance portion 60.

### [Shielding Structure]

As illustrated in FIG. 2 and FIG. 3, the board 1 has the clearance portion 60. The clearance portion 60 is formed by the first clearance region 601 provided in the ground layer 40 illustrated in FIG. 6C, and the second clearance region 602 provided in the shielding ground layers 40a, 40b, and 40c illustrated in FIG. 6D.

The clearance portion 60 can increase the impedance value of the differential signal via pair 30. In a board with high wiring density, the diameter of the signal via tends to be small, making it difficult to achieve the ideal impedance value, for example, 50Ω, in the differential signal via pair. The impedance value is inversely proportional to the ½ power of the via capacity, and increases with the decrease in capacity. Therefore, the board 1 of this embodiment is provided with the clearance portion 60 having a roughly oval shape in the ground layer 40 through which the differential signal via pair 30 passes. The impedance value of the via portion can be increased by increasing the dimensions along the major axis and the minor axis of the clearance portion 60 and decreasing the capacity of the differential signal via pair 30. For this reason, the dimensions along the major axis and the minor axis of the clearance portion 60 are set so that the desired impedance value can be obtained.

However, there is a concern that determining the dimensions of the clearance portion 60 in this manner will increase crosstalk due to the influence of mutual electromagnetic waves between the second differential wiring 22 formed in the first signal layer 10a and the third differential wiring 24 formed in the second signal layer 10b.

Therefore, in this embodiment, first, the eaves portion 61 is provided on the first shielding ground layer 40a disposed between the first signal layer 10a and the second signal layer 10b. The eaves portion 61 is provided so as to protrude inward into the second clearance region 602. Referring to FIG. 6D, the eaves portion 61 is provided by forming the ground solid pattern 401 toward the inside of the second clearance region 602.

When the arrangement direction of the first signal via 30a and the second signal via 30b is taken as the long diameter direction, the first clearance region 601 has a shape in which the short diameter dimension of the central part in the long diameter direction is roughly equal to the diameter of the circular part located at the end in the long diameter direction.

In contrast, the second clearance region 602 has a shape in which the short diameter dimension of the central part in the long diameter direction is smaller than the diameter of the circular part located at the end in the long diameter direction. In other words, by providing the eaves portion 61, the second clearance region 602 has a gourd shape with a narrowing in the central part of the oval or elliptical shape.

The eaves portion 61 is located between the third wiring 22a included in the second differential wiring 22 and the sixth wiring 24b included in the third differential wiring 24. Specifically, the eaves portion 61 is formed in a range that covers the overlapping portion of the second differential wiring 22 and the third differential wiring 24 when the board 1 is viewed from the stacking direction. In this way, by preventing the overlapping portion of the second differential wiring 22 and the third differential wiring 24 from being exposed to the clearance portion 60, crosstalk between the second differential wiring 22 and the third differential wiring 24 can be reduced.

In this embodiment, the second shielding ground layer 40b formed in the same manner as the first shielding ground layer 40a is provided. As a result, shielding ground layers are provided on the upper and lower sides of the first signal layer 10a. As a result, electromagnetic waves generated by the signal transmission of the second differential wiring 22 provided on the first signal layer 10a are prevented from sneaking around the second signal layer 10b.

In addition, in this embodiment, the third shielding ground layer 40c is provided, which is formed in the same manner as the first shielding ground layer 40a. As a result, shielding ground layers are provided above and below the second signal layer 10b. This prevents electromagnetic waves generated by signal transmission of the third differential wiring 24 provided in the second signal layer 10b from sneaking into the first signal layer 10a.

As a result, in this embodiment, crosstalk between the second differential wiring 22 and the third differential wiring 24 is reduced.

Of the first shielding ground layer 40a, the second shielding ground layer 40b, and the third shielding ground layer 40c, it is also possible to have a configuration in which only the first shielding ground layer 40a is provided.

If the multiple ground layers 40 are provided between the first signal layer 10a and the second signal layer 10b, at least one of the multiple ground layers 40 can be the first shielding ground layer 40a.

If the multiple ground layers 40 are provided between the first signal layer 10a and the second signal layer 10b, shielding ground layers can be provided above and below the first signal layer 10a and the second signal layer 10b. In this case, four shielding ground layers are provided. By arranging shielding ground layers above and below the first signal layer 10a, or by arranging shielding ground layers above and below the second signal layer 10b, crosstalk can be reduced more effectively.

In the board 1, the clearance portion 60 obtains a desired impedance value by maintaining a predetermined dimension. The eaves portion 61 covers the overlapping portion between the second differential wiring 22 and the third differential wiring 24 while maintaining the dimensions of the clearance portion 60 that allows a desired impedance value to be obtained. In other words, the board 1 can obtain a desired impedance value and reduce crosstalk between the second differential wiring 22 and the third differential wiring 24.

The shape of the eaves portion 61, in other words, the shape of the second clearance region 602 is not limited to a so-called gourd shape. In this embodiment, the eaves portion 61 has a shape that is symmetrical with respect to an axis extending in the major diameter direction. In contrast, the eaves portion 61 may have a shape that protrudes inward from the second clearance region 602 only in one of the regions on the left and right of the axis.

In short, the eaves portion 61 may have any shape as long as it is formed in a range that covers the overlapping portion between the second differential wiring 22 and the third differential wiring 24 when the board 1 is viewed from the stacking direction.

The first signal layer 10a is provided with the first differential wiring 20, which is connected to a differential signal via pair arranged in an area not illustrated. A clearance portion is also provided around the differential signal via pair. In this case, if there is a location where the first differential wiring 20 faces a wiring provided in another signal layer in the direction along the stacking direction, a eaves portion can be provided as necessary.

In this embodiment, the shielding ground layers 40a, 40b, and 40c on which the eaves portion 61 is provided are set in relation to the second differential wiring 22 and the third differential wiring 24, but the shielding ground layers can be set appropriately based on the relationship of the other differential wirings.

### [Crosstalk Reduction Effect]

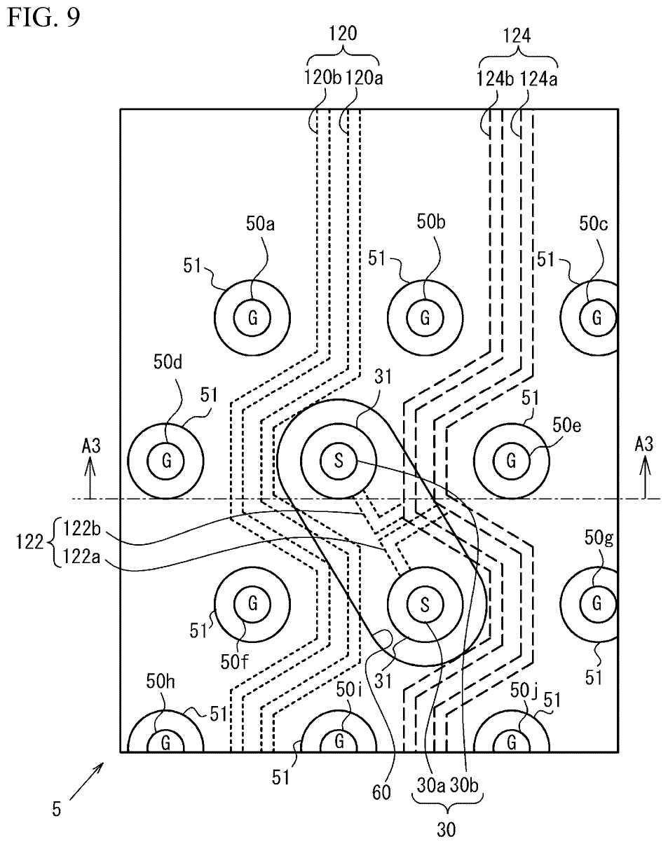

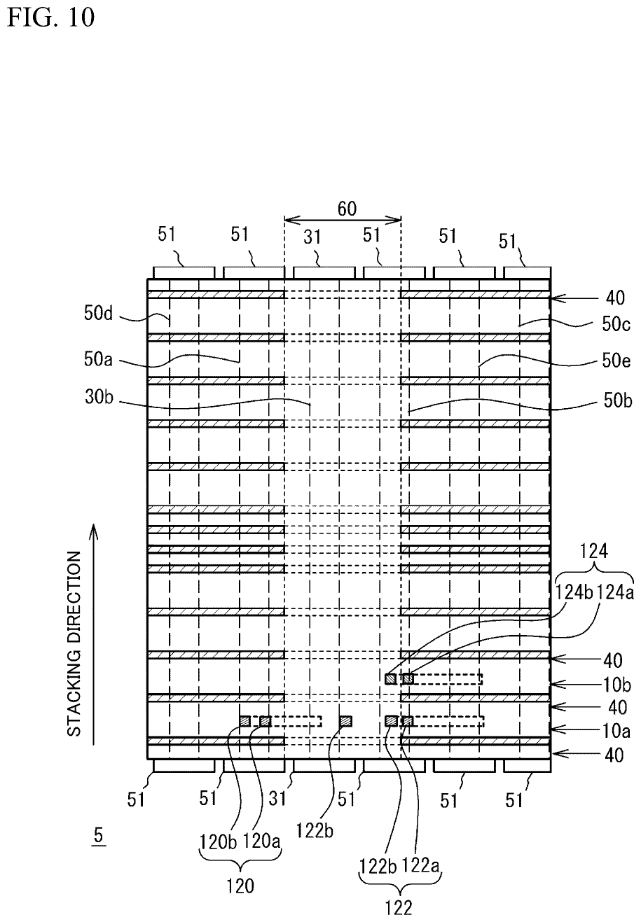

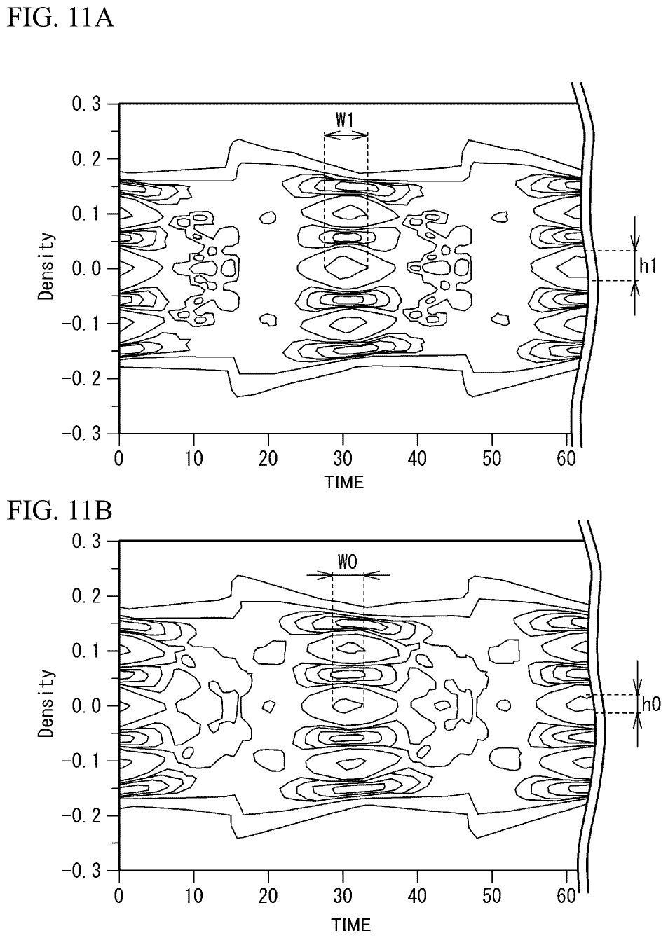

Here, the crosstalk reduction effect of this embodiment will be described in comparison with the comparative example, with reference to FIG. 9 to FIG. 11B. FIG. 9 is a plan view of a partial area of a board 5 of the comparative example. FIG. 10 is a cross-sectional view of the board of the comparative example taken along the line A3-A3 in FIG. 9. FIG. 11A is a graph of the EYE analysis results of the board 1 of the embodiment. FIG. 11B is a graph of the EYE analysis results of the board 5 of the comparative example.

First, the board 5 of the comparative example will be described in comparison with the board 1 of the embodiment. The board 5 includes a fourth differential wiring 120, a fifth differential wiring 122, and a sixth differential wiring 124. The fourth differential wiring 120 corresponds to the first differential wiring 20 in the board 1, and includes a seventh wiring 120a and an eighth wiring 120b. The fifth differential wiring 122 corresponds to the second differential wiring 22 in the board 1, and includes a ninth wiring 122a and a tenth wiring 122b. The sixth differential wiring 124 corresponds to the third differential wiring 24 in the board 1, and includes an eleventh wiring 124a and a twelfth wiring 124b.

The arrangement of the ground vias and differential signal via pairs is the same as that of the board 1, and the same reference numbers are used in the drawings. Furthermore, the fourth differential wiring 120 and the fifth differential wiring 122 are provided in the first signal layer 10a, and the sixth differential wiring 124 is provided in the second signal layer 10b. The board 5 is also common to the board 1 in this respect. However, the ground layer 40 arranged between the first signal layer 10a and the second signal layer 10b is common to the other ground layers 40, and only has the first clearance region 601 (see FIG. 6C). Furthermore, the ground layer 40 arranged below the first signal layer 10a and the ground layer 40 arranged above the second signal layer 10b also only have the first clearance region 601 (see FIG. 6C). In other words, the board 5 does not have the eaves portion 61, and the clearance portion 60 is formed only by the first clearance region 601.

In the fourth differential wiring 120, the fifth differential wiring 122, and the sixth differential wiring 124, the distance between the two wirings in a pair is generally constant. Therefore, two wirings, the seventh wiring 120a and the eighth wiring 120b, are arranged between the ground via 50f and the first signal via 30a. As a result, the distance between the seventh wiring 120a and the first signal via 30a is narrower than the distance R2 between the first wiring 20a and the first signal via 30a in the board 1. Therefore, in the board 5, crosstalk between the seventh wiring 120a and the first signal via 30a is more likely to occur than in the board 1.

In the board 5, as illustrated in FIG. 9, the twelfth wiring 124b of the sixth differential wiring 124 faces a position where it overlaps with the clearance portion 60. This is because two wirings are arranged between the second signal via 30b and the ground via 50e, and as a result, the twelfth wiring 124b is close to the second signal via 30b. Furthermore, the board 5 does not have the eaves portion 61. As a result, in the board 5, as illustrated in FIG. 10, the tenth wiring 122b and the twelfth wiring 124b are directly opposed to each other in the clearance portion 60. Here, the tenth wiring 122b and the twelfth wiring 124b directly opposed to each other means that the tenth wiring 122b and the twelfth wiring 124b are opposed to each other without the ground solid pattern 401 (see FIG. 6D) being present between them. As a result, crosstalk between the fifth differential wiring 122 and the sixth differential wiring 124 is likely to occur.

Here, referring to FIG. 11A illustrating the EYE analysis results of the board 1 of the embodiment, the opening width of the EYE shape is W1 and the opening height is h1. On the other hand, referring to FIG. 11B illustrating the EYE analysis results of the board 5 of the comparative example, the opening width of the EYE shape is W0 and the opening height is h0. Comparing the respective dimensions, the opening width W1>opening width W0 and the opening height h1> opening height h0. Although a detailed explanation of the EYE analysis is omitted here, the results of the EYE analysis show that the larger the dimensions of the opening of the EYE shape, the better the transmission characteristics are and the higher the speed of signal transmission is possible. Therefore, comparing the board 1 of the embodiment with the board 5 of the comparative example, it can be seen that the transmission characteristics of the board 1 are better.

This is thought to be because the wiring form of the board 1 reduces the electromagnetic interference between the differential wiring and the signal via, thereby reducing crosstalk. Furthermore, it is believed that the provision of the eaves portion 61 reduces electromagnetic interference between differential wiring located in the vertical direction, thereby reducing crosstalk.

By reducing crosstalk and improving transmission characteristics, accurate signal transmission can be achieved even under conditions of increased signal speed. The board 1 of this embodiment can be applied to electronic devices that can be applied to AI learning devices and electronic devices capable of high-speed calculations. The board 1 of this embodiment can achieve accurate signal transmission even when high-speed signal transmission is performed in these electronic devices.

### Effects

The effects of the board disclosed in this specification are described below.

In the board 1 disclosed in this specification, the first wiring 20a of the first differential wiring 20 is disposed between the ground via 50f and the first signal via 30a. The second wiring 20b of the first differential wiring 20 is disposed on the opposite side of the first wiring 20a across the ground via 50f. The ground via 50f is sandwiched between the first wiring 20a and the second wiring 20b. This allows the distance between the first wiring 20a of the first differential wiring 20 and the first signal via 30a to be widened, suppressing mutual electromagnetic interference between the two and reducing crosstalk.

The first differential wiring 20 has the fourth portion 202c that is continuous with the third portion 202b that sandwiches the ground via 50f between the first wiring 20a and the second wiring 20b. In the fourth portion 202c, the distance between the first wiring 20a and the second wiring 20b varies depending on the position along the wiring path of the first differential wiring 20. The distance between the first wiring 20a and the second wiring 20b at the end opposite to the end continuing to the third portion 202b is narrower than the distance between the first wiring 20a and the second wiring 20b in the third portion 202b. The fifth portion 203 in which the first wiring 20a and the second wiring 20b are parallel is continuous with the fourth portion 202c. This allows the first wiring 20a and the second wiring 20b to pass between other ground vias. In the example illustrated in FIG. 2, the first wiring 20a and the second wiring 20b can pass between the ground via 50h and the ground via 50i.

The distance between the first wiring 20a and the first signal via 30a in the third portion 202b of the first differential wiring 20 is wider than the distance between the first wiring 20a and the ground via 50f in the third portion 202b. In other words, by arranging the first wiring 20a and the first signal via 30a apart, crosstalk between them can be suppressed and reduced.

In the board 1, the first shielding ground layer 40a is arranged between the first signal layer 10a on which the second differential wiring 22 is formed and the second signal layer 10b on which the third differential wiring 24 is formed. The first shielding ground layer 40a has the second clearance region 602 formed between the ground solid pattern 401 and the differential signal via pair 30. The first shielding ground layer 40a also has the eaves portion 61 that protrudes inward from the second clearance region 602. The eaves portion 61 of the first shielding ground layer 40a is located between the second differential wiring 22 and the third differential wiring 24. This suppresses crosstalk between the second differential wiring 22 and the third differential wiring 24.

The eaves portion 61 is formed in a range that covers the overlapping portion of the second differential wiring 22 and the third differential wiring 24 when the board 1 is viewed from the stacking direction. This effectively suppresses crosstalk between the second differential wiring 22 and the third differential wiring 24.

In the board 1, the second shielding ground layer 40b is disposed below the first signal layer 10a. The second shielding ground layer 40b has the second clearance region 602 and the eaves portion 61, similar to the first shielding ground layer 40a. The second shielding ground layer 40b, together with the first shielding ground layer 40a, can suppress the intrusion of electromagnetic waves emitted by the second differential wiring 22. This suppresses crosstalk between the second differential wiring 22 and the third differential wiring 24.

In the board 1, the third shielding ground layer 40c is disposed above the second signal layer 10b. The third shielding ground layer 40c has the second clearance region 602 and the eaves portion 61, similar to the first shielding ground layer 40a. The third shielding ground layer 40c, together with the first shielding ground layer 40a, can suppress the intrusion of electromagnetic waves emitted by the third differential wiring 24. This suppresses crosstalk between the second differential wiring 22 and the third differential wiring 24.

In the above embodiment, an example is described in which the first another signal line provided in the first signal layer 10a is the second differential wiring 22, and the second another signal line provided in the second signal layer 10b is the third differential wiring 24. The first another signal line provided in the first signal layer 10a and the second another signal line provided in the second signal layer 10b do not necessarily have to be differential wiring, and may be wiring of another form.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various change, substitutions, and alterations could be made hereto without departing from the spirit and scope of the invention.

What is claimed is:

1. A multilayer wiring board having at least a first signal layer and a plurality of ground layers along a stacking direction, the multilayer wiring board comprising:
a first differential wiring that is provided in the first signal layer and includes a first wiring and a second wiring;
a first another signal line provided on the first signal layer;
a signal via that extends along the stacking direction and is electrically connected to the first another signal line; and
a ground via that extends along the stacking direction and is electrically connected to the plurality of ground layers,
wherein the first differential wiring includes a first portion, a second portion continuous with the first portion, and a third portion continuous with the second portion, the first wiring being disposed between the ground via and the signal via adjacent to the ground via, the second wiring being disposed on an opposite side of the first wiring across the ground via, and the ground via being sandwiched between the first wiring and the second wiring.

2. The multilayer wiring board as claimed in claim 1,
wherein the first another signal line provided in the first signal layer is a second differential wiring including a third wiring and a fourth wiring, and
wherein the signal via is either a first signal via extending along the stacking direction and electrically connected to the third wiring, or a second signal via extending along the stacking direction and electrically connected to the fourth wiring.

3. The multilayer wiring board as claimed in claim 1,
wherein the first differential wiring further includes a fourth portion continuous with the third portion, and a fifth portion continuous with the fourth portion, in which a distance between the first wiring and the second wiring is narrower than a distance between the first wiring and the second wiring in the third portion.

4. The multilayer wiring board as claimed in claim 1,
wherein a distance between the first wiring and the signal via in the third portion is wider than a distance between the first wiring and the ground via in the third portion.

5. The multilayer wiring board as claimed in claim 1 further comprising:
a second another signal line provided in a second signal layer different from the first signal layer,
wherein of the plurality of ground layers, a ground layer disposed between the first signal layer and the second signal layer is a shielding ground layer having a clearance region formed between a wiring of the ground layer and the signal via, and a eaves portion protruding inward from the clearance region and positioned between the first another signal line provided in the first signal layer and the second another signal line provided in the second signal layer.

6. The multilayer wiring board as claimed in claim 5,
wherein the first another signal line provided in the first signal layer is a second differential wiring including a third wiring and a fourth wiring,
wherein the second another signal line provided in the second signal layer is a third differential wiring including a fifth wiring and a sixth wiring, and
wherein the eaves portion is located between the second differential wiring and the third differential wiring.

7. The multilayer wiring board as claimed in claim 5,
wherein the eaves portion is formed in an region that covers an overlapping portion between the first another signal line provided in the first signal layer and the second another signal line provided in the second signal layer when the multilayer wiring board is viewed from the stacking direction.

8. The multilayer wiring board as claimed in claim 1 further comprising:
a second another signal line is provided in a second signal layer different from the first signal layer,
wherein of the plurality of ground layers, ground layers arranged above and below the first signal layer are shielding ground layers having a clearance region formed between a wiring of the ground layers and the signal via, and a eaves portion that protrudes inward from the clearance region and is located in a range that covers an overlapping portion between the first another signal line provided in the first signal layer and the second another signal line provided in the second signal layer when the multilayer wiring board is viewed from the stacking direction.

9. The multilayer wiring board as claimed in claim 8,
wherein the first another signal line provided in the first signal layer is a second differential wiring including a third wiring and a fourth wiring, and
wherein the second another signal line provided in the second signal layer is a third differential wiring including a fifth wiring and a sixth wiring.

10. The multilayer wiring board as claimed in claim 1 further comprising:
a second another signal line is provided in a second signal layer different from the first signal layer,
wherein of the plurality of ground layers, ground layers arranged above and below the second signal layer are shielding ground layers having a clearance region formed between a wiring of the ground layers and the signal via, and a eaves portion that protrudes inward from the clearance region and is located in a range that covers an overlapping portion between the first another signal line provided in the first signal layer and the second another signal line provided in the second signal layer when the multilayer wiring board is viewed from the stacking direction.

11. The multilayer wiring board as claimed claim 10,
wherein the first another signal line provided in the first signal layer is a second differential wiring including a third wiring and a fourth wiring, and
wherein the second another signal line provided in the second signal layer is a third differential wiring including a fifth wiring and a sixth wiring.

12. An electronic device comprising:
a multilayer wiring board having at least a first signal layer and a plurality of ground layers along a stacking direction, the multilayer wiring board comprising:
a first differential wiring that is provided in the first signal layer and includes a first wiring and a second wiring;
a first another signal line provided on the first signal layer;
a signal via that extends along the stacking direction and is electrically connected to the first another signal line; and
a ground via that extends along the stacking direction and is electrically connected to the plurality of ground layers,
wherein the first differential wiring includes a first portion, a second portion continuous with the first portion, and a third portion continuous with the second portion, the first wiring being disposed between the ground via and the signal via adjacent to the ground via, the second wiring being disposed on an opposite side of the first wiring across the ground via, and the ground via being sandwiched between the first wiring and the second wiring; and
an electronic component mounted on the multilayer wiring board.
